(19) United States
(12) Patent Application Publication
(10) Pub. No.: US 2025/0387772 A1
(43) Pub. Date: Dec. 25, 2025

(54) FLUORINE PLASMA RESISTANT DIELECTRIC COMPOSITIONS

(71) Applicant: Applied Materials, Inc., Santa Clara, CA (US)

(72) Inventors: Amir H. TAVAKOLI, San Jose, CA (US); Jian LI, Fremont, CA (US)

(21) Appl. No.: 18/749,270

(22) Filed: Jun. 20, 2024

(51) Int. Cl. B01J 19/02; B01J 19/08; H01L 21/67; H01L 21/687

(52) U.S. Cl. CPC B01J 19/02; B01J 19/08; H01L 21/67103; H01L 21/68757; B01J 2219/0263; B01J 2219/0898

(57) ABSTRACT

The present disclosure generally provides plasma processing chambers and methods thereof. The plasma processing chambers comprises a chamber body covered by a lid, the chamber body and the lid defining a chamber interior volume. A substrate support is disposed on a support shaft within the chamber interior volume. The substrate support includes a body having a top layer including a ceramic composition and a lower layer including a nitride, an oxide, or a carbide. A mesh is embedded in the lower layer. One or more heating elements are disposed below the mesh proximal to the support shaft.

### BACKGROUND

### Field

Embodiments of the present disclosure generally relate to substrate supports including electrostatic chucks, and related apparatus, methods, and processing chambers (e.g., semiconductor processing chambers).

### Description of the Related Art

Various semiconductor processing techniques implement one or more ceramic components that are subject to harsh chemical conductions during plasma processing techniques at temperatures of greater than 400 °C,. For example, functional ceramic components (e.g., electrostatic chucks and heaters) can be subject to wafer processing or chamber cleaning techniques using CF₄ or NF₃ plasma processing techniques. Conventional dielectric ceramic components used for high temperature wafer chucking through Johnson-Rahbek (J-R) effects are formed by a bulk material including undoped or doped aluminum nitride dielectrics. Unfortunately, the aluminum nitride dielectrics are limited to temperatures of less than 700 °C, due to inadequate electrical resistivity for maintaining a substrate on the ceramic component via a clamping force. Moreover, even at lower temperatures the aluminum nitride dielectrics can degrade due to the inherent low chemical resistance of the material to fluorination.

Conventional approaches to prevent degradation of ceramic components in processing chambers have focused on chemically modifying the aluminum nitride dielectric compositions through doping or co-doping of the original composition with the other chemistries. Unfortunately, the doped aluminum nitride is still limited to temperatures of up to 700 °C. Other conventional approaches, have focused on providing a fluorine resistant coating. Unfortunately, the fluorine resistant coatings can crack and/or delaminate during processing, which can lead to particle contamination during substrate processing. Moreover, the cracking and/or delamination of the fluorine resistant coating requires complex regeneration processes to correct the cracks, thereby increasing downtime and manufacturing costs.

Accordingly, there is a need for improved substrate supports made of bulk ceramics.

### SUMMARY

Embodiments of the present disclosure generally relate to substrate supports including electrostatic chucks, and related apparatus, methods, and processing chambers (e.g., semiconductor processing chambers).

In one or more embodiments, the present disclosure generally provides plasma processing chambers. The plasma processing chambers comprises a chamber body covered by a lid, the chamber body and the lid defining a chamber interior volume. A substrate support is disposed on a support shaft within the chamber interior volume. The substrate support includes a body having a top layer including a ceramic composition and a lower layer including a nitride, an oxide, or a carbide. A mesh is embedded in the lower layer. One or more heating elements are disposed below the mesh proximal to the support shaft.

In one or more embodiments, the present disclosure also generally provides substrate supports for disposition in processing chambers. The substrate supports include a body having a top layer that includes a ceramic composition and a lower layer that includes a nitride, an oxide, or a carbide. The substrate supports include a support shaft, a mesh embedded in the lower layer, and one or more heating elements disposed below the mesh proximal to the support shaft.

In one or more embodiments, the present disclosure also generally provides substrate for disposition in processing chambers. The substrate supports include a body. The body includes a top layer including a ceramic composition. The top layer includes a first binary metal composition, a second binary metal composition, and a complex metal composition. The body includes a lower layer including a nitride, an oxide, or a carbide. The substrate support includes a support shaft, a mesh embedded in the lower layer, and one or more heating elements disposed below the mesh proximal to the support shaft.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a substrate processing chamber in accordance with embodiments of the present disclosure.

FIG. 2 is a schematic cross-sectional of a substrate support in accordance with embodiments of the present disclosure.

FIGS. 3A-3G are diagrammatic representations of a ceramic composition having a binary oxide composition or a tertiary oxide composition in accordance with embodiments of the present disclosure.

FIGS. 4A and 4B are graphical representations of electrical resistivities of ceramic compositions in accordance with embodiments of the present disclosure.

FIGS. 5A and 5B are graphical representations of plasma etch resistances of ceramic compositions in accordance with embodiments of the present disclosure.

FIGS. 6A and 6B are graphical representations of plasma etch depths and particle amounts of ceramic compositions in accordance with embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to ceramic compositions and methods of production thereof for use as a bulk material of a ceramic component, e.g., a substrate support, heater, and/or electrostatic chuck, in a processing chamber. In some embodiments, the ceramic compositions can include an oxide composition. In some embodiments, the oxide composition can include one or more of a binary metal oxide composition and/or a ternary metal oxide composition. In some embodiments, the ceramic composition can include can allow for high temperature, e.g., about 400 °C to about 950 °C, chemical vapor deposition processes, while allowing for controllable resistivity from about 1x10¹² Ω•cm to about 1x10⁸ Ω•cm. In some embodiments, the ceramic composition can increase the longevity of the ceramic component, e.g., a substrate support, heater, and/or electrostatic chuck, due to the increased chemical compatibility between the ceramic component and the cleaning plasma chemistry, e.g., NF₃ compatibility. In some embodiments, the ceramic composition can provide for fluorine resistance, e.g., CF₄ resistance, compared to conventional bulk material compositions, e.g., aluminum nitride, thereby providing increased longevity for the ceramic composition.

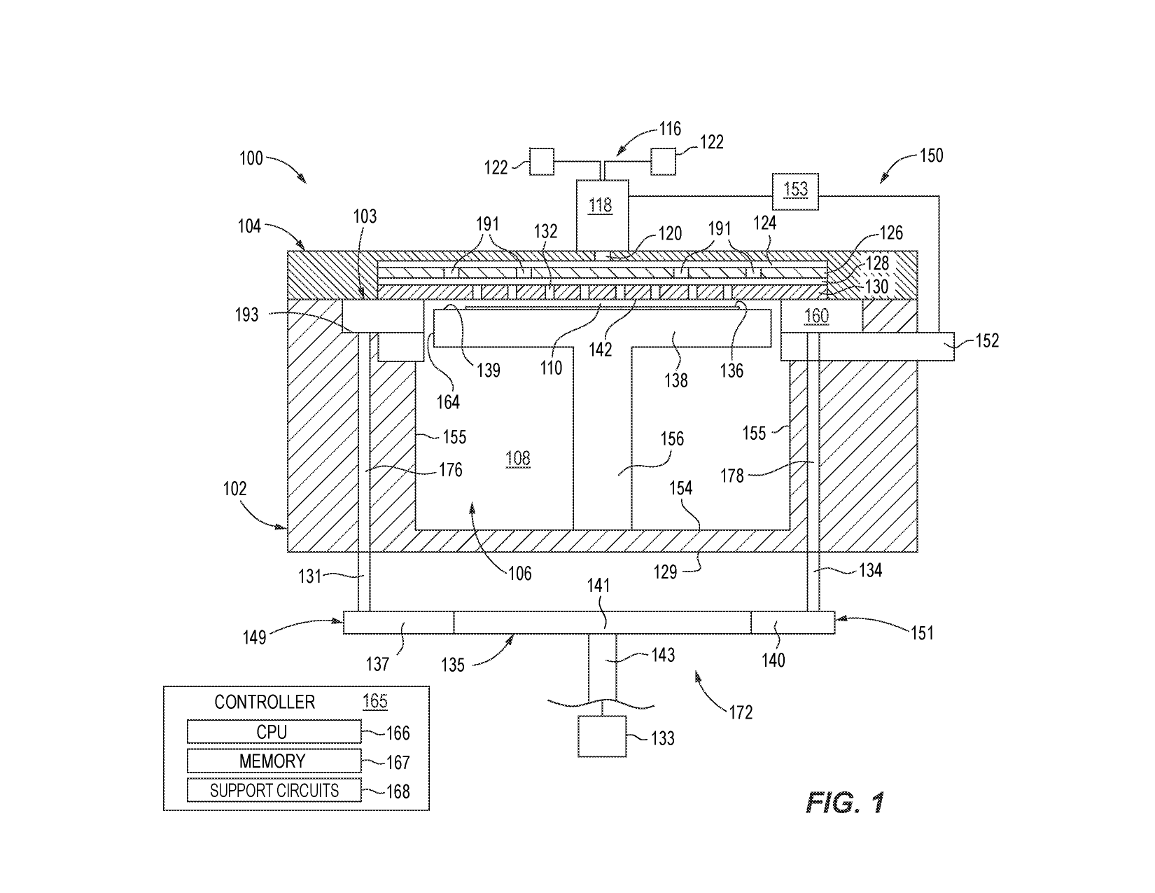

FIG. 1A is a schematic cross-sectional view of a substrate processing chamber 100, according to one implementation. The substrate processing chamber 100 may be, for example, a chemical vapor deposition (CVD) chamber or a plasma enhanced CVD chamber. The substrate processing chamber 100 has a chamber body 102 and a chamber lid 104. The chamber body 102 includes an internal volume 106 therein. The internal volume 106 is the space defined by the chamber body 102 and the chamber lid 104.

The substrate processing chamber 100 includes a gas distribution assembly 116 coupled to or disposed in the chamber lid 104 to deliver a flow of one or more gases into a processing region 110. The gas distribution assembly 116 includes a gas manifold 118 coupled to a gas inlet passage 120 formed in the chamber lid 104. The gas manifold 118 receives a flow of gases from one or more gas sources 122 (two are shown). One or more of the gas sources 122 may include a source of cleaning fluid such as a remote plasma source (RPS). During a cleaning process, the RPS may generate cleaning radicals using a reactive gas (e.g., a halogen-containing gas or oxygen-containing gas, among others). For example, fluorine-containing reactive gases such as NF₃ may be used to generate a flow of cleaning fluid containing fluorine radicals. Alternatively, oxygen gas (e.g., O₂) may be used to generate a flow of cleaning fluid containing oxygen radicals. The flow of gases received from the one or more gas sources 122 distributes across a gas box 124, flows through a plurality of openings 191 of a backing plate 126, and further distributes across a plenum 128 defined by the backing plate 126 and a faceplate 130. The faceplate 130 is disposed in the internal volume 106 between the plenum 128 and the processing region 110. The flow of gases then flows into the processing region 110 of the internal volume 106 through a plurality of openings 132 of the faceplate 130. The gases enter the processing region 110 through a lower surface 142 of the faceplate 130 which faces the processing region 110.

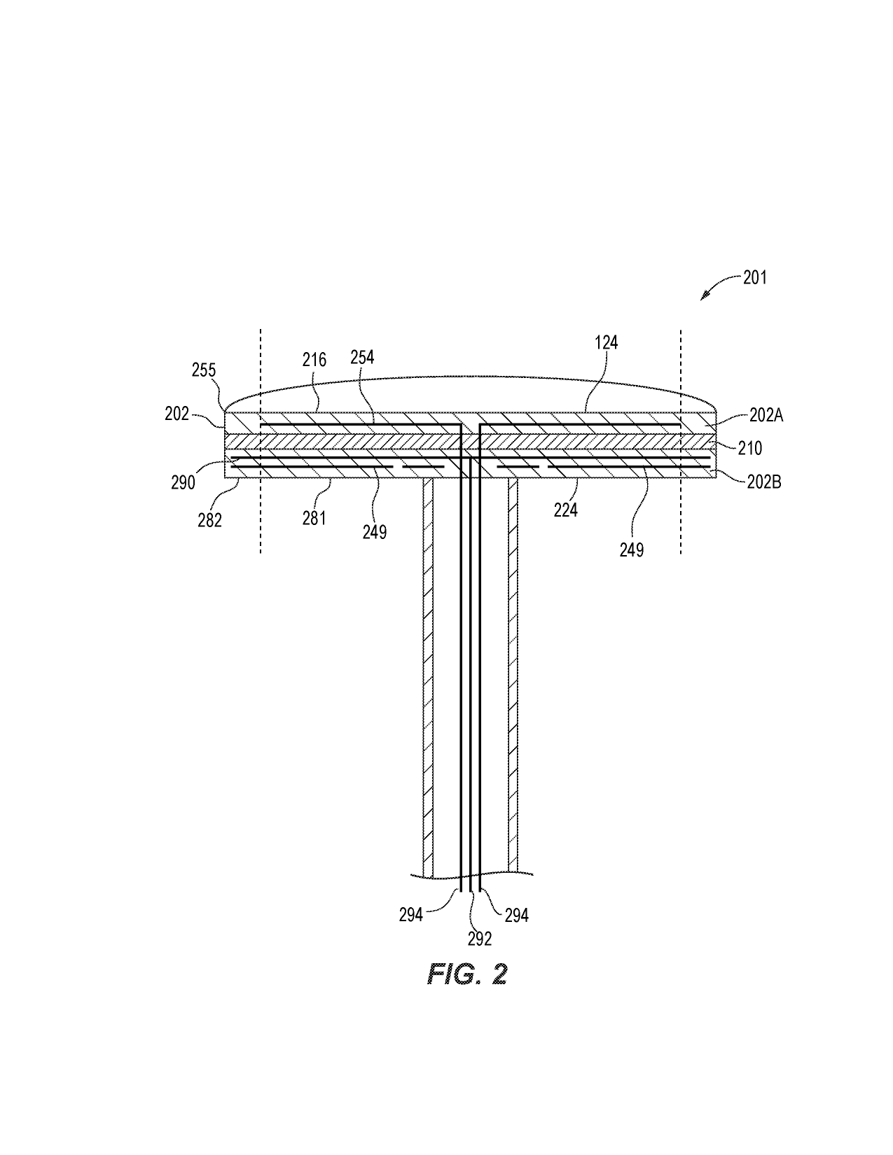

The internal volume 106 includes a substrate support 138 disposed in the chamber body 102. The substrate support 138 supports a substrate 136 within the substrate processing chamber 100. The substrate support 138 supports the substrate 136 on a support surface 139 of the substrate support 138. The substrate support 138 has a bottom neck 156. The substrate support 138 includes a heater and an electrode disposed therein, as shown below in reference to FIG. 2. The electrode may supply alternating current (AC), direct current (DC) voltage, or radio frequency (RF) energy to the internal volume 106 and/or the processing region 110.

The substrate support 138 is movably disposed in the internal volume 106 by a lift system (not shown). Movement of the substrate support 138 facilitates transfer of the substrate 136 to and from the internal volume 106 through a slit valve (not shown) formed through the chamber body 102. The substrate support 138 may also be moved to different processing positions for processing of the substrate 136.

During substrate processing, as gases flow through the plurality of openings 132 and into the processing region 110, a heater heats the substrate support 138 and the support surface 139. Also during substrate processing, the electrode in the substrate support 138 propagates the alternating current (AC), direct current (DC) voltage, or radio frequency (RF) energy to facilitate plasma generation in the processing region 110 and/or to facilitate chucking of the substrate 136 to the substrate support 138. The gases in the processing region 110, heating of the substrate support 138, and energy from the electrode in the substrate support 138 facilitate deposition of a film onto the substrate 136 during substrate processing. The faceplate 130 (which is grounded via coupling to the chamber body 102) and the electrode of the substrate support 138 facilitate formation of a capacitive plasma coupling. When power is supplied to the electrode in the substrate support 138, an electric field is generated between the faceplate 130 and substrate support 138 such that atoms of gases present in the processing region 110 between the substrate support 138 and the faceplate 130 are ionized and release electrons. The ionized atoms accelerate to the substrate support 138 to facilitate film formation on the substrate 136.

A pumping device 103 is disposed in the substrate processing chamber 100. The pumping device 103 facilitates removal of gases from the internal volume 106 and processing region 110. The gases exhausted by the pumping device 103 include one or more of a processing gas, a processing residue, a cleaning gas, a cleaning residue, and/or a purge gas. The processing residue may result from the process of depositing a film onto the substrate 136.

The pumping device 103 includes a pumping ring 160 disposed on a stepped surface 193 of the chamber body 102. The stepped surface 193 is stepped upwards from a bottom surface 154 of the chamber body 102. The stepped surface 193 supports the pumping ring 160. The pumping ring 160 includes a body 107 (shown in FIG. 1B). The body 107 of the pumping ring 160 is made from material including one or more of aluminum, aluminum oxide, and/or aluminum nitride. The pumping ring 160 is fluidly coupled to a foreline 172 through a first conduit 176 and a second conduit 178. The foreline 172 includes a first vertical conduit 131, a second vertical conduit 134, a horizontal conduit 135, and an exit conduit 143. The exit conduit 143 in one example is a third vertical conduit. In one example, the first conduit 176 and the second conduit 178 are openings formed in the chamber body 102 and extend from the stepped surface 193 to a lower outer surface 129 of the chamber body 102. Alternatively, the first conduit 176 and the second conduit 178 may be tubes or other flow devices that extend between a surface of the chamber body 102, such as the bottom surface 154, and the pumping ring 160. As an example, the first conduit 176 and the second conduit 178 may be part of the first vertical conduit 131 and the second vertical conduit 134, respectively. In such an example, the first vertical conduit 131 and the second vertical conduit 134 may extend through the chamber body 102 and be coupled to the pumping ring 160.

The first conduit 176 is fluidly coupled to the pumping ring 160 at a first end and the first vertical conduit 131 of the foreline 172 at a second end. The second conduit 178 is fluidly coupled to the pumping ring 160 at a first end and the second vertical conduit 134 of the foreline 172 at a second end. The first vertical conduit 131 and the second vertical conduit 134 are fluidly coupled to the horizontal conduit 135. The horizontal conduit 135 includes a first portion 137 coupled to the first vertical conduit 131, a second portion 140 coupled to the second vertical conduit 134, and a third portion 141 coupled to the exit conduit 143. The horizontal conduit 135 includes a first end 149 adjacent to the first vertical conduit 131 and a second end 151 adjacent to the second vertical conduit 134. The horizontal conduit 135 may be made up of a single body or fabricated from two or more components.

The first conduit 176, second conduit 178, first vertical conduit 131, second vertical conduit 134, and horizontal conduit 135 are configured to direct gases therethrough. The first conduit 176, second conduit 178, first vertical conduit 131 and second vertical conduit 134 need not be completely vertical and may be angled or may include one or more bends and/or angles. The horizontal conduit 135 need not be completely horizontal and may be angled or may include one or more bends and/or angles.

In one embodiment, which can be combined with other embodiments, the pumping ring 160 is disposed inside of the chamber body 102 while the first vertical conduit 131, the second vertical conduit 134, the horizontal conduit 135, and the exit conduit 143 are disposed or extend outside of the chamber body 102. In such an embodiment, the first conduit 176 and the second conduit 178 are disposed through the chamber body 102.

The exit conduit 143 is fluidly coupled to a vacuum pump 133 to control the pressure within the processing region 110 and to exhaust gases and residue from the processing region 110. The vacuum pump 133 exhausts gases from the processing region 110 through the pumping ring 160, the first conduit 176, the second conduit 178, the first vertical conduit 131, the second vertical conduit 134, the horizontal conduit 135, and the exit conduit 143 of the foreline 172.

A cleaning assembly 150 is coupled to the substrate processing chamber 100. The manifold 118 and/or one or more gas sources 122 may form part of the cleaning assembly 150. The cleaning assembly 150 diverts at least a portion of a flow of cleaning fluid from the manifold 118 to a sidewall 155 of the chamber body 102. The cleaning assembly 150 generally includes a distribution ring for introducing the cleaning fluid to the internal volume 106 through the sidewall 155 of the chamber body 102 and an isolation valve 153 regulating flow of cleaning fluid from the manifold 118 to the distribution ring. The distribution ring is disposed in the chamber body 102 adjacent to and/or below the pumping ring 160. The flow of cleaning fluid exiting the distribution ring may be directed primarily through a lower portion 108 of the internal volume 106 including along the bottom surface 154 and the sidewall 155 of the chamber body 102 before being exhausted through the pumping ring 160. The lower portion 108 of the internal volume 106 may refer to a region defined vertically between the bottom surface 154 and the pumping ring 160 and defined laterally between opposing sidewalls 155 of the chamber body 102. The cleaning fluid and radicals contained in the lower portion 108 of the internal volume 106 may contact and clean surfaces inside the substrate processing chamber 100 located below the faceplate 130 such as the bottom neck 156 of the substrate support 138, substrate support edge 164, sidewalls 155, and pumping ring 160.

In one embodiment (not shown), which can be combined with other embodiments, the cleaning fluid may contact and clean an edge of the faceplate 130. For example, processing residue may accumulate along an outer edge region of the lower surface 142 of the faceplate 130 located proximate an interface between the faceplate 130 and an inner radial wall of at least one of the pumping ring or insulator ring as described in more detail below. In such examples, upward flow of cleaning fluid from the lower portion 108 of the internal volume 106 to the pumping ring 160 may facilitate cleaning of the faceplate edge, unlike conventional approaches in which cleaning flow does not contact the faceplate edge. The cleaning assembly 150 is described in more detail below with regard to FIG. 1B.

A controller 165, such as a programmable computer, is connected to the substrate processing chamber 100 and the cleaning assembly 150. For example, the controller 165 may be connected to the lift system of the substrate support 138 for directing movement of the substrate support 138 to different processing positions as shown in FIGS. 2A-2D. The controller 165 may be connected to the isolation valve 153 for opening and closing the isolation valve 153 to regulate flow of cleaning fluid from the manifold 118 to the distribution ring. The controller 165 may be connected to various other components of the substrate processing chamber 100 and the cleaning assembly 150.

The controller 165 includes a programmable central processing unit (CPU) 166, which is operable with a memory 167 (e.g., non-volatile memory) and support circuits 168. The support circuits 168 are conventionally coupled to the CPU 166 and comprise cache, clock circuits, input/output subsystems, power supplies, and the like, and combinations thereof coupled to the various components of the substrate processing chamber 100 and the cleaning assembly 150.

In some embodiments, the CPU 166 is one of any form of general purpose computer processor used in an industrial setting, such as a programmable logic controller (PLC), for controlling various monitoring system component and sub-processors. The memory 167, coupled to the CPU 166, is non-transitory and is typically one or more of readily available memory such as random access memory (RAM), read only memory (ROM), floppy disk drive, hard disk, or any other form of digital storage, local or remote.

Herein, the memory 167 is in the form of a computer-readable storage media containing instructions (e.g., non-volatile memory), that when executed by the CPU 166, facilitates the operation of the substrate processing chamber 100 and the cleaning assembly 150. The instructions in the memory 167 are in the form of a program product such as a program that implements the methods of the present disclosure (e.g., middleware application, equipment software application etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

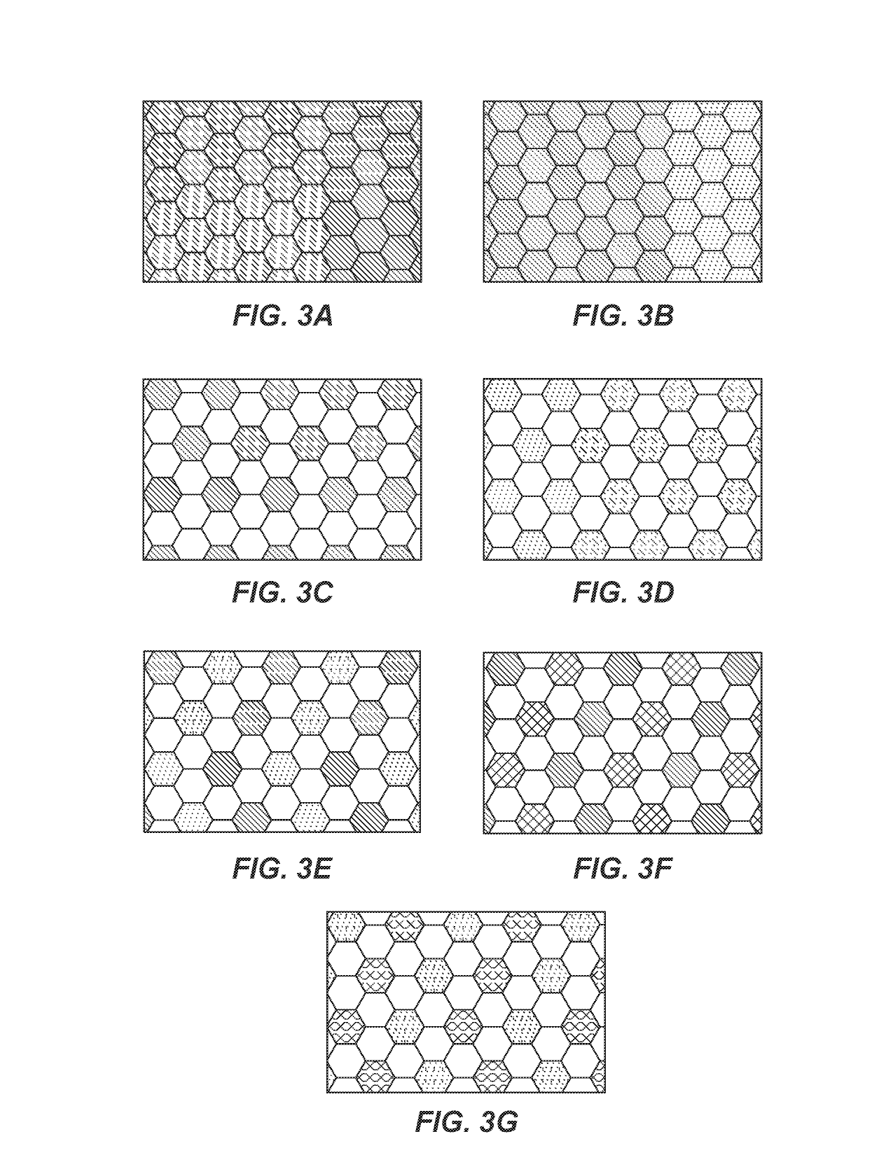

FIG. 2 depicts a schematic partial side view of the substrate support 138 in accordance with at least one example of the present disclosure. The substrate support has an electrostatic chuck 201 having a body 202. In some embodiments, the body 202 includes a top layer 202A and a lower layer 202B. In some embodiments, the top layer 202A may include an oxide composition, as described below, in reference to FIG. 3. In one example, the top layer 202A includes an oxide composition including a binary composition and/or ternary metal oxide composition, as described below, in reference to FIG. 3. In some embodiments, the lower layer 202B includes a nitride composition, and/or an oxide composition, and/or a carbide composition.

The top layer 202A and the lower layer 202B are separated by a bond layer 210. In some embodiments, the bond layer is formed by brazing techniques (e.g., active metal brazing, passive/indirect metal brazing). In some embodiments, the bond layer is formed by diffusion bonding after sandwiching a metal foil between the top layer 202A and the lower layer 202B. In some embodiments, the bond layer 210 can include a composite formulation comprising both dielectric material compositions used in the top layer 202A and the lower layer 202B. In this case, a green body of the dielectric bond layer is sandwiched between the green body of top layer 202A and the green body of the lower layer 202B and the stack of three layers are co-fired to form the body 202.

In some embodiments, the bond layer 210 can include a thickness of about 0.1 mm to about 3 mm, e.g., about 0.1 mm to about 2.5 mm, about 0.5 mm to about 2 mm, about 1.0 mm to about 1.5 mm, or about 1.1 mm to about 1.4 mm. In some embodiments, the bond layer 210 can include a thermal conductivity of greater than 20 W/mK, e.g., about 20 W/mK about 30 W/mK, about 40 W/mK, about 50 W/mK, or about 200 W/mK. In some embodiments, the bond layer 210 can include a coefficient of thermal expansion (CTE) of about 3 x 10⁻⁶ per Kelvin (/K) to about 10 x10⁻⁶/K, e.g., about 3 x 10⁻⁶/K to about 9 x 10⁻⁶/K, about 4 x 10⁻⁶/K to about 8 x 10⁻⁶/K or about 5 x 10⁻⁶/K to about 7 x 10⁻⁶/K. In some embodiments, the bond layer 210 can include a thermal shock resistance of about 400 °C to about 900 °C, e.g., about 400 °C to about 800 °C, about 500 °C to about 700 °C, or about 600 °C to about 650 °C.

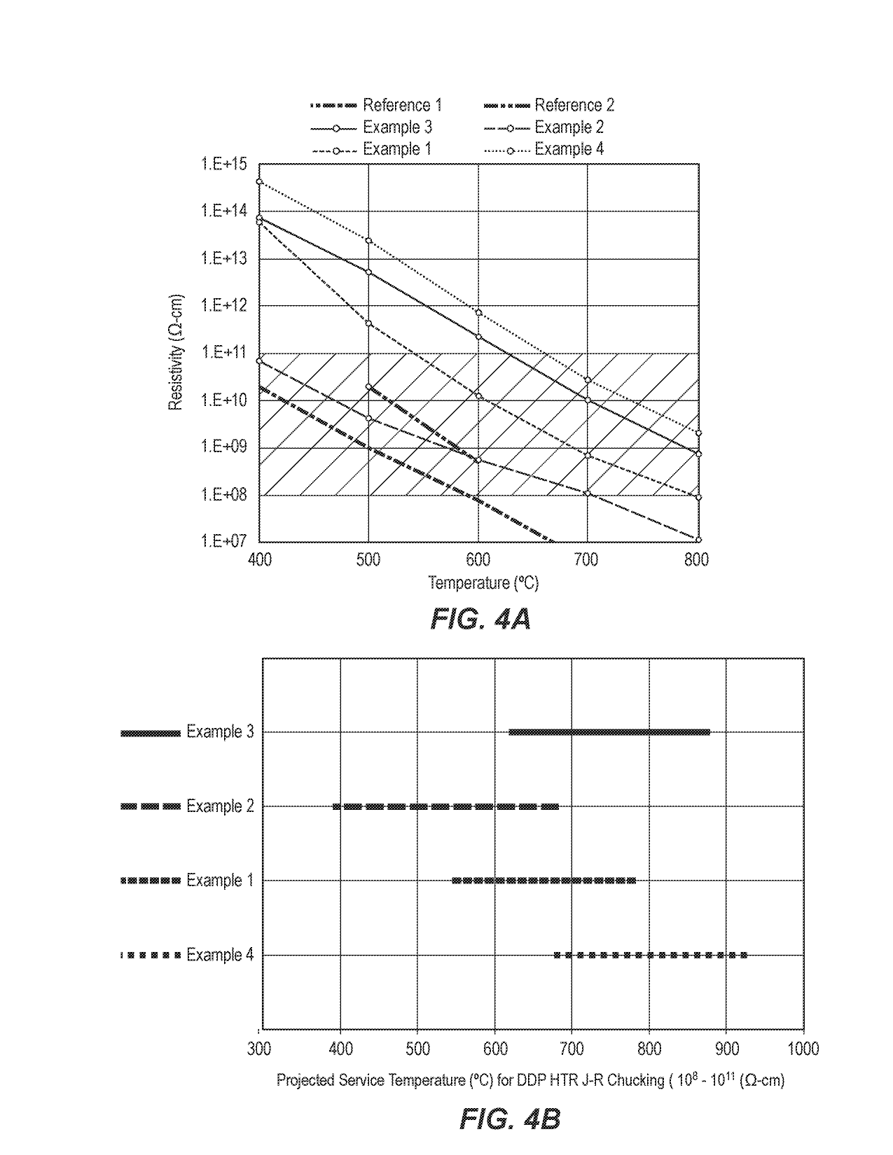

In some embodiments, the bond layer 210 can include an oxide composition. The oxide composition can include a mixture of the binary metal oxide composition and/or ternary metal oxide composition, and the nitride composition. In some embodiments, the bond layer 210 can include about 0 wt % to about 100 wt% of the oxide composition, and about 0 wt % to about 100 wt% of the nitride composition, as described below, in reference to FIGS. 4A-4D.

The body 202 includes a first side 216 configured to support the substrate 136136 and a second side 224 opposite the first side 216. The electrostatic chuck 201 has an outer diameter 255. The body 202 has an inner portion 281 and an outer portion 282, the inner portion 281 extending from the center of the electrostatic chuck 201 and the outer portion extending from the edge of the inner portion 281 to the outer diameter 255 and surrounding the inner portion 281. The substrate 136 is disposed in the inner portion 281 and an edge electrode is disposed on the outer portion 282. The body 202 thickness between the first side 216 and the second side 224 is between about 18 mm and 22 mm, such as about 20 mm.

The one or more chucking electrodes 254 can be embedded in the inner portion 281 of the body 202 immediately adjacent to the first side 216. The chucking electrodes 254, when energized, electrostatically chuck the substrate 136 to the first side 216 of the electrostatic chuck 201. The one or more chucking electrodes 254 may be monopolar or bipolar. In some examples, the electrostatic chuck 201 provides Coulombic chucking. In some examples, the electrostatic chuck 201 provides Johnsen-Rahbek chucking. The chucking electrodes 254 may be coupled to a bias power supply via wire 294.

Embedded below the chucking electrodes 254 is a mesh 290, e.g., a single continuous piece of woven conductive fibers, for example conductive wires, forming a mesh 290. The mesh 290 can be formed from a mesh sheet that is for example less than 0.1 to approximately 1.0 mm thick. The mesh is, for example, composed of a woven mat or sheet of individual nickel molybdenum wires, each wire having a thickness of diameter on the order of 0.05 to 1.0 mm or greater. The individual wires in the unitary mesh sheet comprise for example, a cross pattern, where one plurality of wire runs in a first direction and the second plurality runs in a second direction orthogonal to the first direction, and each wire extending in the first direction alternatingly crosses below a wire, then over the next wire, below the next wire, etc. of the second plurality of wires. Three sets of wire each set oriented with their lengths in one of a first, second and third direction may also be employed, where each of the first second and third directions are offset from one another by 60 degrees. Other patterns are also appropriate. The mesh 290 may be coupled to the bias power supply for biasing and shaping the plasma sheath or otherwise modifying the properties of a plasma in the processing volume adjacent to the outer circumference of a substrate on the substrate receiving portion through a power supply connection, for example the aforementioned wire 292 (rod). The wire 292 is for example a solid Ni-Mo rod, for example 5 mm diameter. The mesh 290 can be configured to operate independently of the chucking electrodes 254. However, the chucking electrodes 254 may optionally be coupled to the bias power supply for shaping the plasma sheath in addition to the chucking power supply. A variable capacitor may be disposed between the bias power supply and the chucking electrodes 254 for isolating the chucking electrodes 254 from the mesh 290. In one example, the mesh 290 may be energized while the chucking electrodes 254 are de-energized. However, it should be appreciated that the chucking electrodes 254 may be energized at the same time the mesh 290 is energized or alternately while the mesh 290 is de-energized.

In some examples, RF energy supplied by the bias power supply may have a frequency of between about 350KHz to about 60MHz. In one example, the bias power supply is configured to generate the RF signal overlaid on a pulsed voltage signal of the negative pulsed DC power source. In one example, the voltage waveform of the negative pulsed DC power source may include a pulsed voltage signal range of about at 0.2Hz to about 20Hz with a duty cycle ranging from 10% to 100% overlaid with the RF signal of about 350KHz to about 60 Mhz. The negative pulsed DC power source is configured to provide a power profile to correct plasma sheath bending and maintain a substantially flat plasma sheath profile across the substrate 136.

The one or more heating elements 249 are embedded in the body 202 below the mesh 290. The heating elements 249 extend horizontally within the body 202 to between about 1.5 mm to about 3 mm from the outer diameter 255 of the body 202. In one example, the distance the heating elements 249 extend horizontally within the body 202 is about 2.5 mm from the outer diameter 255 of the body 202.

The heating elements 249 may be arranged in one or more zones to control a temperature of the electrostatic chuck 201. For example, the heating elements 249 may be arranged in one, two or four zones for supplying a temperature to the substrate 136. The heating elements 249 may have a hollow in the center of the diameter of the body 202 through which power supply wires may pass. The heating elements 249 are coupled to a power source, e.g., an AC power source, to power the heating elements 249. The one or more heating elements 249 are configured to supply a temperature to the substrate of about 200 °C to about 900 °C. For example, the electrostatic chuck 201 is configured to operate at temperatures exceeding 700 °C, such as about 750 °C.

The body 202 can include a top layer 202A and a lower layer 202B. In some embodiments, the top layer 202A can include a ceramic composition, including at least a binary metal oxide and/or a ternary metal oxide. In some embodiments, the ceramic composition can include a binary metal oxide including at least a first metal, as shown in FIG. 3A. In some embodiments, the first metal composition can include a rare earth metal, e.g., cerium, erbium, holmium, lanthanum, lutetium, scandium, samarium, terbium, yttrium, ytterbium, or a combination thereof. For example, the first metal composition can include cerium oxide, erbium oxide, holmium oxide, lanthanum oxide, lutetium oxide, scandium oxide, samarium oxide, terbium oxide, yttrium oxide, ytterbium oxide, or combinations thereof. Without being bound by theory, a ceramic composition including a binary metal oxide can allow for chemical vapor deposition processes to be performed at temperatures of about 400 °C to about 800 °C, while still providing a resistivity of 1x10¹¹ Ω•cm to about 1x10⁸ Ω•cm.

In some embodiments, the ceramic composition can include a ternary metal oxide including a first metal and a second metal, as shown in FIG. 3B. In some embodiments, the first metal can include a rare earth metal, e.g., cerium, erbium, holmium, lanthanum, lutetium, scandium, samarium, terbium, yttrium, ytterbium, or a combination thereof. In some embodiments, the second metal can include a rare earth metal, e.g., cerium, erbium, holmium, lanthanum, lutetium, scandium, samarium, terbium, yttrium, ytterbium, or a combination thereof. For example, the ceramic composition can include cerium erbium oxide, cerium holmium oxide, cerium lanthanum oxide, cerium lutetium oxide, cerium scandium oxide, cerium samarium oxide, cerium terbium oxide, cerium yttrium oxide, cerium ytterbium oxide, or combinations. As a further example, the ceramic composition can include erbium holmium oxide, erbium lanthanum oxide, erbium lutetium oxide, erbium scandium oxide, erbium samarium oxide, erbium terbium oxide, erbium yttrium oxide, erbium ytterbium oxide, or combinations. As a further example, the ceramic composition can include holmium lanthanum oxide, holmium lutetium oxide, holmium scandium oxide, holmium samarium oxide, holmium terbium oxide, holmium yttrium oxide, holmium ytterbium oxide, or combinations. As a further example, the ceramic composition can include lanthanum lutetium oxide, lanthanum scandium oxide, lanthanum samarium oxide, lanthanum terbium oxide, lanthanum yttrium oxide, lanthanum ytterbium oxide, or combinations. As a further example, the ceramic composition can include lutetium scandium oxide, lutetium samarium oxide, lutetium terbium oxide, lutetium yttrium oxide, lutetium ytterbium oxide, or combinations. As a further example, the ceramic composition can include scandium samarium oxide, scandium terbium oxide, scandium yttrium oxide, scandium ytterbium oxide, or combinations. As a further example, the ceramic composition can include samarium terbium oxide, samarium yttrium oxide, samarium ytterbium oxide, or combinations. As a further example, the ceramic composition can include terbium yttrium oxide, terbium ytterbium oxide, or combinations. As a further example, the ceramic composition can include yttrium ytterbium oxide. Without being bound by theory, a ceramic composition including a ternary metal composition can allow chemical vapor deposition processes to be performed at temperatures of about 400 °C to about 800 °C, while still providing a resistivity of 1x10¹¹ Ω•cm to about 1x10⁸ Ω•cm and high fluorine etch resistance.

In some embodiments, the first metal can include a Group 2-14 metal, e.g., barium, beryllium, calcium, hafnium, magnesium, niobium, strontium, tantalum, thallium, zirconium, or a combination thereof. In some embodiments, the second metal can include a Group 2-14 metal, e.g., aluminum, boron, chromium, iron, manganese, molybdenum, nickel, silicon, titanium, vanadium, or a combination thereof. For example, the ternary oxide composition can include magnesium vanadium oxide, hafnium aluminum oxide, strontium titanium oxide, or a combination thereof.

In some embodiments, the ceramic composition can include a first binary metal composition and a second binary metal composition, as shown in FIG. 3C. In some embodiments, the first binary metal composition can include a Group 2-14 metal oxide, e.g., barium oxide, beryllium oxide, calcium oxide, hafnium oxide, magnesium oxide, niobium oxide, strontium oxide, tantalum oxide, thallium oxide, zirconium oxide, or a combination thereof. In some embodiments, the second binary metal composition can include a rare earth metal oxide, e.g., cerium oxide, erbium oxide, holmium, lanthanum, lutetium, scandium, samarium, terbium, yttrium, ytterbium, or a combination thereof. In some embodiments, the first metal composition may be present in the ceramic composition at a weight percent of about 0.01 wt% to about 99.99 wt%, e.g., about 0.1 wt% to about 99.9 wt%, about 1 wt% to about 90 wt%, about 10 wt% to about 80 wt%, about 20 wt% to about 70 wt%, about 30 wt% to about 60 wt%, or about 40 wt% to about 50 wt%. In some embodiments, the second metal composition may be present in the ceramic composition at a weight percent of about 0.01 wt% to about 99.99 wt%, e.g., about 0.1 wt% to about 99.9 wt%, about 1 wt% to about 90 wt%, about 10 wt% to about 80 wt%, about 20 wt% to about 70 wt%, about 30 wt% to about 60 wt%, or about 40 wt% to about 50 wt%. For example, the ceramic composition can include about 40 wt% of the first binary metal composition and about 60 wt% of the second binary metal composition. Without being bound by theory, a ceramic composition including a first binary metal composition and a second binary metal composition can allow for chemical vapor deposition processes to be performed at temperatures of about 500 °C to about 900 °C, while still providing a resistivity of 1x10¹¹ Ω•cm to about 1x10⁸ Ω•cm.

In some embodiments, the ceramic composition can include a binary metal composition, e.g., a Group 2-14 metal oxide, and a ternary metal composition, e.g., a ternary metal oxide including a first metal such as barium, beryllium, calcium, hafnium, magnesium, niobium, strontium, tantalum, thallium, or zirconium, and a second metal such as aluminum, boron, chromium, iron, manganese, molybdenum, nickel, silicon, titanium, or vanadium, as shown in FIG. 3D. In some embodiments, the binary metal composition may be present in the ceramic composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the ternary metal composition may be present in the ceramic composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the ceramic composition can include about 30 wt% of the binary metal composition and about 70 wt% of the ternary metal composition. Without being bound by theory, a ceramic composition including a binary metal composition and a ternary metal composition can allow for chemical vapor deposition processes to be performed at temperatures of about 500 °C to about 900 °C, while still providing a resistivity of 1x10¹¹ Ω•cm to about 1x10⁸ Ω•cm.

In some embodiments, the ceramic composition can include a first binary metal composition, e.g., a Group 2-14 metal oxide, a second binary metal composition, e.g., a rare earth metal oxide, and a ternary metal composition, e.g., a ternary metal oxide including a first metal such as barium, beryllium, calcium, hafnium, magnesium, niobium, strontium, tantalum, thallium, or zirconium, and a second metal such as aluminum, boron, chromium, iron, manganese, molybdenum, nickel, silicon, titanium, or vanadium, as shown in FIG. 3E. In some embodiments, the first binary metal composition may be present in the ceramic composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the second binary metal composition may be present in the ceramic composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the ternary metal composition may be present in the ceramic composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the ceramic composition can include about 20 wt% of the first binary metal composition, about 60 wt% of the second binary metal composition, and about 20 wt% of the ternary metal composition. Without being bound by theory, a ceramic composition including a first binary metal composition, a second binary metal composition, and a ternary metal oxide can allow chemical vapor deposition processes to be performed at temperatures of about 550 °C to about 950 °C, while still providing a resistivity of 1x10¹¹ Ω•cm to about 1x10⁸ Ω•cm and high fluorine etch resistance.

In some embodiments, the ceramic composition can include a first binary metal composition, e.g., a Group 2-14 metal oxide, a second binary metal composition, e.g., a rare earth metal oxide, and a complex metal composition, e.g., a ternary metal oxide including one or more rare earth metals, e.g., cerium, erbium, holmium, lanthanum, lutetium, scandium, samarium, terbium, yttrium, ytterbium, and a Group 2-14 metal such as aluminum, boron, chromium, iron, manganese, molybdenum, nickel, silicon, titanium, or vanadium, as shown in FIG. 3F. In some embodiments, the first binary metal composition may be present in the ceramic composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the second binary metal composition may be present in the ceramic composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the complex metal composition may be present in the ceramic composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the ceramic composition can include about 60 wt% of the first binary metal composition, about 20 wt% of the second binary metal composition, and about 20 wt% of the complex metal composition. Without being bound by theory, a ceramic composition including a first binary metal composition, a second binary metal composition, and a complex oxide can allow chemical vapor deposition processes to be performed at temperatures of about 550 °C to about 950 °C, while still providing a resistivity of 1x10¹¹ Ω•cm to about 1x10⁸ Ω•cm, and a high fluorine etch resistance.

In some embodiments, the ceramic composition can include a binary metal composition, e.g., a Group 2-14 metal oxide, a ternary metal composition, e.g., a ternary metal oxide including a first metal such as barium, beryllium, calcium, hafnium, magnesium, niobium, strontium, tantalum, thallium, or zirconium, and a second metal such as aluminum, boron, chromium, iron, manganese, molybdenum, nickel, silicon, titanium, or vanadium, and a complex metal composition, e.g., a ternary metal oxide including one or more rare earth metals, e.g., cerium, erbium, holmium, lanthanum, lutetium, scandium, samarium, terbium, yttrium, ytterbium, and a Group 2-14 metal such as aluminum, boron, chromium, iron, manganese, molybdenum, nickel, silicon, titanium, or vanadium, as shown in FIG. 3G. In some embodiments, the binary metal composition may be present in the ceramic composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the first ternary metal composition may be present in the ceramic composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the complex metal composition may be present in the ceramic composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the ceramic composition can include about 10 wt% of the first binary metal composition, about 500 wt% of the second binary metal composition, and about 40 wt% of the complex metal composition. Without being bound by theory, a ceramic composition including a binary metal composition, a ternary metal composition, and a complex oxide can allow chemical vapor deposition processes to be performed at temperatures of about 550 °C to about 950 °C, while still providing a resistivity of 1x10¹¹ Ω•cm to about 1x10⁸ Ω•cm, and a high fluorine etch resistance.

### Examples

A first ceramic composition including a binary metal oxide (Example 1), a second ceramic composition including a ternary metal oxide (Example 2), a third ceramic composition include a first binary metal composition and a second binary metal composition (Example 3), and a fourth ceramic composition including a binary metal composition, a ternary metal composition, and a complex metal composition (Example 4) were compared to reference ceramic compositions including undoped and/or doped aluminum nitride (Reference 1 and Reference 2, respectively), as shown in FIG. 4A. The ceramic composition working temperatures were determined while providing a resistivity range of about 1x10¹¹ Ω•cm to about 1x10⁸ Ω•cm. The reference ceramic composition resulted in the lowest working temperature range, from 400 °C to about 600 °C, as shown in FIG. 4A. Example 1 had a working temperature range of about 550 °C to about 780 °C, as shown in FIG. 4B. Example 2 had a working temperature range of about 380 °C to about 680 °C, as shown in FIG. 4B. Example 3 had a working temperature range of about 620 °C to about 880 °C, as shown in FIG. 4B. Example 4 had a working temperature range of about 660 °C to about 950 °C, as shown in FIG. 4B.

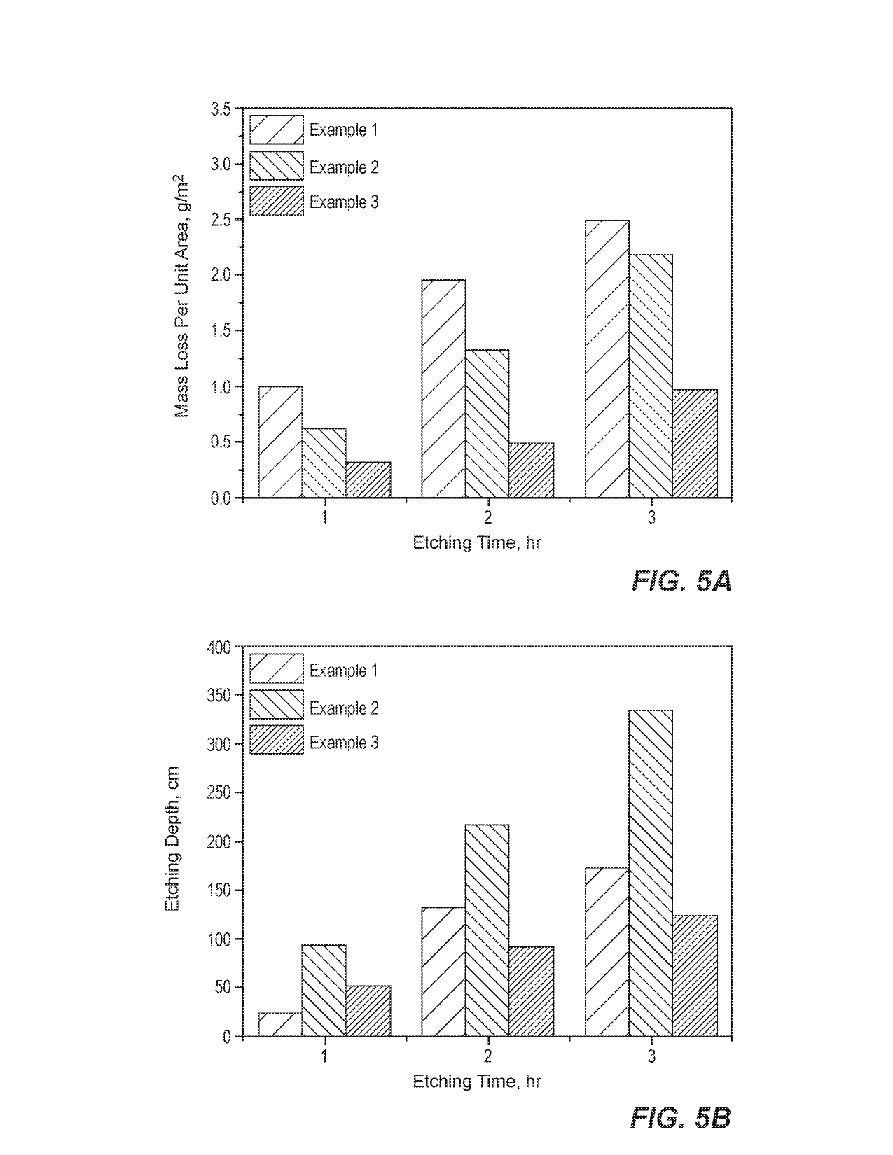

A fluorinated plasma etching process was performed on the first ceramic composition, second ceramic composition, and third ceramic composition using an RF source power of 0.5 kW, a bias power of 0.1 kW, a pressure of 10 mTorr. Carbon tetra fluoride and oxygen were introduced into the processing chamber at a flow rate of 40 sccm and 10 sccm, respectively. After 3 hours, the third ceramic composition resulted in the lowest mass loss per unit area as shown in FIG. 5A. Additionally, after 3 hours, the third ceramic composition resulted in the lowest etching depthas shown in FIG. 5B.

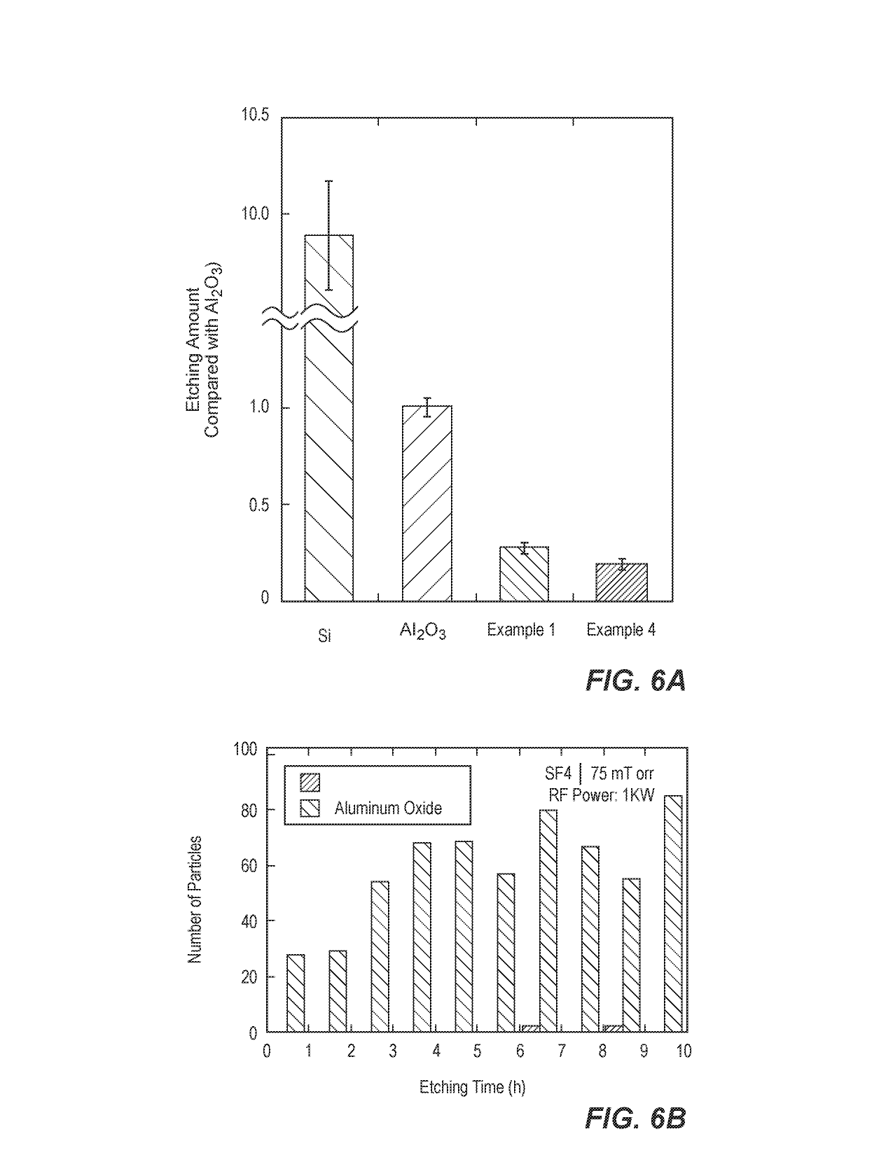

Example 1 and Example 4 were compared to silica, or aluminum oxide during a fluorinated plasma etching process including a pressure of 75 mTorr, an RF power of 1 kW, an etching time of 2 hour, and an etchant of carbon tetrafluoride. Both Example 1 and Example 4 resulted in a reduced etching amount during the fluorinated plasma etching process, as shown in FIG. 6A. Additionally, Example 4 showed prolonged fluorinated plasma etch resistance after up to 7 hours, where aluminum oxide resulted in more than 28x particles being generated in the processing volume, as shown in FIG. 6B.

Overall, the ceramic compositions of the present disclosure can increase the longevity of the ceramic component, e.g., a substrate support, heater, and/or electrostatic chuck, due to the increased chemical compatibility between the ceramic component and the cleaning plasma chemistry. In some embodiments, the ceramic composition can provide for fluorine resistance, e.g., CF₄ resistance, compared to conventional bulk material compositions, e.g., aluminum nitride, thereby providing increased longevity for the ceramic composition.

As used herein, the term “proximal”, refers to a location that is adjacent to and/or near to a point of reference such as an origin or a point of attachment, e.g., a distance of about 0 mm to about 10 mm, e.g., about 0 mm to about 9 mm, about 1 mm to about 8 mm, about 1 mm to about 5 mm, or about 2 mm to about 4 mm. For example, the heating elements may be proximal to the support shaft, in which the heating elements are disposed near and/or adjacent to the support shaft.

Although the present disclosure mainly describes substrate supports (e.g., heaters and/or electrostatic chucks), the methods and apparatus can be more generally applied to other components used in process chambers, such as showerheads or other components that are exposed to harsh process conditions.

It is contemplated that one or more aspects disclosed herein may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof.

What is claimed is:

1. A plasma processing chamber, comprising:
a chamber body covered by a lid, the chamber body and the lid defining a chamber interior volume;
a substrate support disposed on a support shaft within the chamber interior volume, the substrate support comprising:
a body having a top layer comprising a ceramic composition and a lower layer comprising a nitride, an oxide, or a carbide;
a mesh embedded in the lower layer; and
one or more heating elements disposed below the mesh proximal to the support shaft.

2. The plasma processing chamber of claim 1, wherein the ceramic composition comprises a binary metal composition, a ternary metal composition, a complex metal composition, or a combination thereof.

3. The plasma processing chamber of claim 2, wherein the binary metal composition comprises a binary metal oxide.

4. The plasma processing chamber of claim 3, wherein the binary metal oxide comprises a rare earth metal comprising cerium, erbium, holmium, lanthanum, lutetium, scandium, samarium, terbium, yttrium, ytterbium, or a combination thereof.

5. The plasma processing chamber of claim 3, wherein the binary metal oxide comprises a Group 2-14. metal comprising barium, beryllium, calcium, hafnium, magnesium, niobium, strontium, tantalum, thallium, zirconium, or a combination thereof.

6. The plasma processing chamber of claim 2, wherein the ternary metal composition comprises a ternary metal oxide.

7. The plasma processing chamber of claim 6, wherein the ternary metal oxide comprises:
a first metal comprising a rare earth metal comprising cerium, erbium, holmium, lanthanum, lutetium, scandium, samarium, terbium, yttrium, or ytterbium; and
a second metal comprising cerium, erbium, holmium, lanthanum, lutetium, scandium, samarium, terbium, yttrium, or ytterbium.

8. The plasma processing chamber of claim 6, wherein the ternary metal oxide comprises:
a first metal comprising a Group 2-14. metal comprising barium, beryllium, calcium, hafnium, magnesium, niobium, strontium, tantalum, thallium, or zirconium; and
a second metal comprising a Group 2-14. metal comprising aluminum, boron, chromium, iron, manganese, molybdenum, nickel, silicon, titanium, or vanadium.

9. The plasma processing chamber of claim 2, wherein the complex metal composition comprises:
a first metal comprising a rare earth metal comprising cerium, erbium, holmium, lanthanum, lutetium, scandium, samarium, terbium, yttrium, or ytterbium; and
a second metal comprising a Group 2-14. metal comprising aluminum, boron, chromium, iron, manganese, molybdenum, nickel, silicon, titanium, or vanadium.

10. The plasma processing chamber of claim 1, wherein the top layer comprises a resistivity range of about 1x10¹² Ω•cm to about 1x10⁸ Ω•cm.

11. A substrate support for disposition in a processing chamber, the substrate support comprising:
a body having a top layer comprising a ceramic composition and a lower layer comprising a nitride, an oxide, or a carbide;
a support shaft;
a mesh embedded in the lower layer; and
one or more heating elements disposed below the mesh proximal to the support shaft.

12. The substrate support of claim 10, wherein the ceramic composition comprises a first binary metal composition, a second binary metal composition, a ternary metal composition, or a combination thereof.

13. The substrate support of claim 12, wherein:
the first binary metal composition comprises a Group 2-14. metal comprising barium, beryllium, calcium, hafnium, magnesium, niobium, strontium, tantalum, thallium, zirconium, or a combination thereof; and
the second binary metal composition comprises a rare earth metal oxide comprising cerium, erbium, holmium, lanthanum, lutetium, scandium, samarium, terbium, yttrium, ytterbium, or a combination thereof.

14. The substrate support of claim 12, wherein the ternary metal composition comprises a ternary metal oxide.

15. The substrate support of claim 14, wherein the ternary metal oxide comprises:
a first metal comprising a rare earth metal comprising cerium, erbium, holmium, lanthanum, lutetium, scandium, samarium, terbium, yttrium, or ytterbium; and
a second metal comprising cerium, erbium, holmium, lanthanum, lutetium, scandium, samarium, terbium, yttrium, or ytterbium.

16. The substrate support of claim 14, wherein the ternary metal oxide comprises:
a first metal comprising a Group 2-14 metal comprising barium, beryllium, calcium, hafnium, magnesium, niobium, strontium, tantalum, thallium, or zirconium; and
a second metal comprising a Group 2-14 metal comprising aluminum, boron, chromium, iron, manganese, molybdenum, nickel, silicon, titanium, or vanadium.

17. The substrate support of claim 11, wherein the top layer comprises a resistivity range of about 1x10¹² Ω•cm to about 1x10⁸ Ω•cm.

18. A substrate support for disposition in a processing chamber, the substrate support comprising:
a body, the body comprising:
a top layer comprising a ceramic composition, the top layer comprising a first binary metal composition, a second binary metal composition, and a complex metal composition, and a lower layer comprising a nitride, an oxide, or a carbide;
a support shaft;
a mesh embedded in the lower layer; and
one or more heating elements disposed below the mesh proximal to the support shaft.

19. The substrate support of claim 18, wherein:
the first binary metal composition comprises a binary metal oxide comprising a Group 2-14. metal barium, beryllium, calcium, hafnium, magnesium, niobium, strontium, tantalum, thallium, zirconium, or a combination thereof;
the second binary metal composition comprises a binary metal oxide comprising a rare earth metal oxide comprising cerium, erbium, holmium, lanthanum, lutetium, scandium, samarium, terbium, yttrium, ytterbium, or a combination thereof; and
the complex metal composition comprises:
a first metal comprising a rare earth metal comprising cerium, erbium, holmium, lanthanum, lutetium, scandium, samarium, terbium, yttrium, or ytterbium; and
a second metal comprising a Group 2-14. metal comprising aluminum, boron, chromium, iron, manganese, molybdenum, nickel, silicon, titanium, or vanadium.

20. The substrate support of claim 18, wherein the top layer comprises a resistivity range of about 1x10¹² Ω•cm to about 1x10⁸ Ω•cm.
